(19) United States
(12) Patent Application Publication
(10) Pub. No.: US 2026/0196570 A1
(43) Pub. Date: Jul. 9, 2026

(54) METHOD FOR MANUFACTURING NON-AQUEOUS ELECTROLYTE SECONDARY BATTERY

(71) Applicant: Prime Planet Energy & Solutions, Inc., Tokyo (JP)

(72) Inventors: Masaki MAEDA, Kobe-shi (JP); Yuma KAMIYAMA, Osaka-shi (JP)

(21) Appl. No.: 19/432,877

(22) Filed: Dec. 24, 2025

(30) Foreign Application Priority Data
Jan. 7, 2025 (JP) 2025-002250

(51) Int. Cl. H01M 10/058; G01R 31/52; H01M 4/02; H01M 4/13; H01M 10/0525; H01M 10/44; H01M 10/615

(52) U.S. Cl. CPC H01M 10/058; G01R 31/52; H01M 4/13; H01M 10/0525; H01M 10/44; H01M 10/615; H01M 2004/021; H01M 2004/027

(57) ABSTRACT

A method for manufacturing a non-aqueous electrolyte secondary battery includes: preparing an assembly having an electrode body and a non-aqueous electrolyte put in a battery case; charging the assembly to a predetermined voltage V0; storing the assembly at 45° C. or higher for 3 hours or longer; adjusting the assembly to a voltage V1 of 3.585 V or higher; when a temperature at the start of a temperature raise of the assembly is T1, raising the temperature of the assembly to a temperature T2 higher than T1 and then reducing the temperature of the assembly to a temperature T3 lower than T2; and performing a self-discharge test at a temperature T4 lower than T2.

### CROSS REFERENCE TO RELATED APPLICATION

The present application claims priority based on Japanese Patent Application No. 2025-002250 filed on Jan. 7, 2025 and the entire contents of this application are incorporated herein by reference.

### BACKGROUND

### 1. Technical Field

The present disclosure relates to improvements in test accuracy for a micro-short circuit cell by reducing the temperature dependence of voltage and particularly to a method for manufacturing a non-aqueous electrolyte secondary battery which has achieved the improvements.

### 2. Background

Non-aqueous electrolyte secondary batteries such as lithium ion secondary batteries have been used suitably for portable power sources in e.g., personal computers and mobile terminals and driving power sources mounted in vehicles, e.g., BEV (electric vehicles), HEV (hybrid vehicles) and PHEV (plug-in hybrid vehicles). From the viewpoint of safety when using these products, it is desired not to use a non-aqueous electrolyte secondary battery (cell) having said internal short circuit for the products even when it is an internal short circuit at a minute level (micro-short circuit). Therefore, a technique of identifying batteries with an internal short circuit in the step of manufacturing a non-aqueous electrolyte secondary battery has been studied. Patent Literature 1, for example, is provided as prior art which discloses this type of technique. Patent Literature 1 discloses a technique for judging whether or not an internal short circuit occurs by measuring self-discharge voltage in the process of manufacturing a lithium ion secondary battery.

### SUMMARY

Patent Literature 1 (Japanese Patent Application Laid-Open No. 2012-84332) discloses a technique for judging whether or not an internal short circuit occurs based on differences in battery voltage before and after self-discharge by allowing a lithium ion secondary battery charged to a charging voltage of 3.52 V to 3.6 V to self-discharge in the manufacturing process. The battery voltage varies with temperature change; however, when the charging voltage is within the above range, the amount of change is less and the battery voltage can be measured with high accuracy, that is, it can be judged whether or not an internal short circuit occurs with good accuracy.

However, the battery voltage of a non-aqueous electrolyte secondary battery such as a lithium ion secondary battery not only depends on temperatures at the time of measurement but also can vary depending on temperature change history until measuring the battery voltage. Therefore, there is a risk that even when charging is performed to a charging voltage at which the amount of change in battery voltage with temperature change is less, the accuracy of a test about whether or not an internal short circuit occurs will be reduced depending on temperature change history until a self-discharge test.

The present invention has been made in view of the above circumstances and an object thereof is to provide a method for manufacturing a non-aqueous electrolyte secondary batter, which can separate cells having a micro-internal short circuit and cells not having the internal short circuit with good accuracy in the process of manufacturing a non-aqueous electrolyte secondary battery.

The method for manufacturing a non-aqueous electrolyte secondary battery disclosed herein is a method for manufacturing a non-aqueous electrolyte secondary battery including an electrode body including a positive electrode and a negative electrode, and a non-aqueous electrolyte, the method including the following steps:
an assembly preparation step of preparing an assembly having the electrode body and the non-aqueous electrolyte put in a battery case;
an initial charging step of charging the assembly to a predetermined voltage V0;
an aging step of storing the assembly at 45° C. or higher for 3 hours or longer after the initial charging step;
a voltage adjustment step of adjusting the assembly to a voltage V1 of 3.585 V or higher after the aging step;
a temperature history adjustment step of, when a temperature at the start of a temperature raise of the assembly is considered T1, including a temperature raise of the assembly to a temperature T2 higher than the T1 and then a temperature reduction of the assembly to a temperature T3 lower than the T2 after the voltage adjustment step; and
a self-discharge test step of performing a self-discharge test at a temperature T4 lower than the T2 after the temperature history adjustment step.

According to the method for manufacturing a non-aqueous electrolyte secondary battery having the above structure, the temperature dependence of battery voltage is a positive value and the absolute value thereof can be reduced. Then, the battery voltage can be measured with high accuracy, that is, it can be tested whether or not an internal short circuit occurs.

In one suitable aspect of the method for manufacturing a non-aqueous electrolyte secondary battery disclosed herein, the above negative electrode includes a negative electrode substrate and a negative electrode active material layer formed on at least one surface of the above negative electrode substrate, and the density of the above negative electrode active material layer is 1.4 g/mL or more and the coated amount is 185 g/m² or more. Because of this, a charge carrier (lithium ion in the case of lithium ion secondary batteries) is released from an electric double layer on the interface of the negative electrode into the electrolyte by increases in the negative electrode potential with increases in the temperature of the secondary battery. After that, since the charge carrier does not easily return to the electric double layer on the interface of the negative electrode, the temperature dependence of battery voltage derived from changes in the concentration of the charge carrier in the electric double layer on the interface of the negative electrode, which is caused by the subsequent variations in the temperature of the secondary battery, can be further reduced.

In one suitable aspect of the method for manufacturing a non-aqueous electrolyte secondary battery disclosed herein, the above temperature history adjustment step is performed once or twice or more repeatedly. When the step is repeated twice or more, temperature differences ST between the above T2 and the above T1 in the respective temperature history adjustment steps are the same as or different from each other. This can promote release of the charge carrier by increases in the negative electrode potential with increases in the temperature of the secondary battery and further reduce the temperature dependence of battery voltage.

In one suitable aspect of the method for manufacturing a non-aqueous electrolyte secondary battery disclosed herein, a temperature difference between the above T2 and the above T4 is 3° C. or higher. This can promote release of the charge carrier by increases in the negative electrode potential with increases in the temperature of the secondary battery and further reduce the temperature dependence of battery voltage.

### BRIEF DESCRIPTION OF THE DRAWINGS

FIG. 1 is a perspective view schematically showing a non-aqueous electrolyte secondary battery.

FIG. 2 is a schematic longitudinal section taken along the line II-II in FIG. 1.

FIG. 3 is a perspective view schematically showing an electrode body group attached to a sealing plate.

FIG. 4 is a perspective view schematically showing an electrode body to which the second positive electrode current collecting part and the second negative electrode current collecting part are attached.

FIG. 5 is a schematic diagram showing the structure of a wound electrode body.

FIG. 6 is a flow chart showing part of a method for manufacturing a non-aqueous electrolyte secondary battery.

FIG. 7(A) is a graph showing the temperature dependence of battery voltage at any charging voltages measured under an environment of 25° C., and FIG. 7(B) is an enlarged graph of part of FIG. 7(A).

FIG. 8 is a graph schematically showing the temperature change process of an assembly in the manufacturing process.

FIG. 9 is a graph showing the temperature dependence of battery voltage according to one embodiment.

### DETAILED DESCRIPTION

Some embodiments of the technique disclosed herein will now be described with reference to the drawings. The same signs are assigned to members and parts having the same actions in the following drawings for illustration. Also, the dimensional relationships (length, width, thickness, etc.) in each drawing do not reflect actual dimensional relationships. It should be noted that things which are other than the matters particularly mentioned in the present specification, and are necessary for implementation of the technique disclosed herein (for example, general structures and manufacturing processes for the electric storage device which do not characterize the present disclosure) can be understood as design matters of those skilled in the art based on conventional techniques in the art. The technique disclosed herein can be performed based on the contents disclosed in the present specification and common general technical knowledge in the art. In addition, the following description is not intended to limit the present disclosure to the following embodiments.

The notation of “A to B” showing a range means “A or more and B or less” in the present specification. It also encompasses the meanings of “above A” and “less than B.” Also, the “electric storage device” in the specification means a device which can be charged and discharged. The electric storage device encompasses batteries such as primary batteries and secondary batteries (e.g. a non-aqueous electrolyte secondary batteries such as lithium ion secondary batteries or nickel-metal hydride batteries) and capacitors (physical batteries) such as electric double layer capacitors. The electrolyte may be any of a liquid electrolyte (an electrolyte solution), a gel electrolyte and a solid electrolyte. A lithium ion secondary battery (hereinafter simply referred to as “battery 100”), one embodiment of the electric storage device disclosed herein, will now be described as an example.

### 1. Structure of Non-Aqueous Electrolyte Secondary Battery

In the specification, the “non-aqueous electrolyte secondary battery” is an electric storage device which can be repeatedly charged and discharged with the transfer of a charge carrier between a positive electrode and a negative electrode and a term to refer to all devices having a non-aqueous electrolyte, and is a concept encompassing so-called storage batteries (chemical batteries) such as lithium ion secondary batteries and sodium ion secondary batteries, and capacitors (physical batteries) such as electric double layer capacitors. Main constituents for the non-aqueous electrolyte secondary battery according to the present disclosure will now be described. It should be noted that as constituents for other non-aqueous electrolyte secondary batteries such as lithium ion secondary batteries which are not described herein, conventionally known constituents can be used.

In the non-aqueous electrolyte secondary battery according to the present disclosure, an electrode body including a positive electrode and a negative electrode, and a non-aqueous electrolyte are put in a battery case.

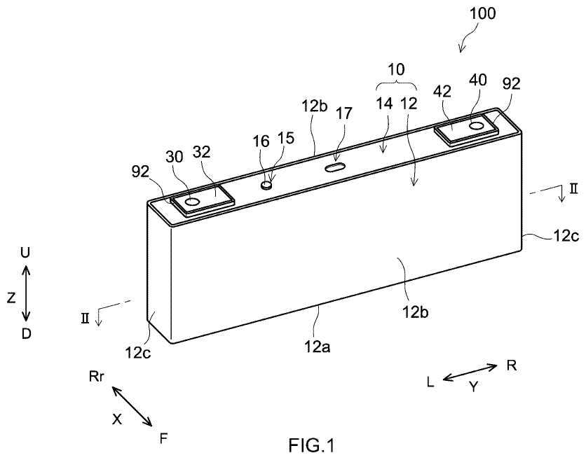

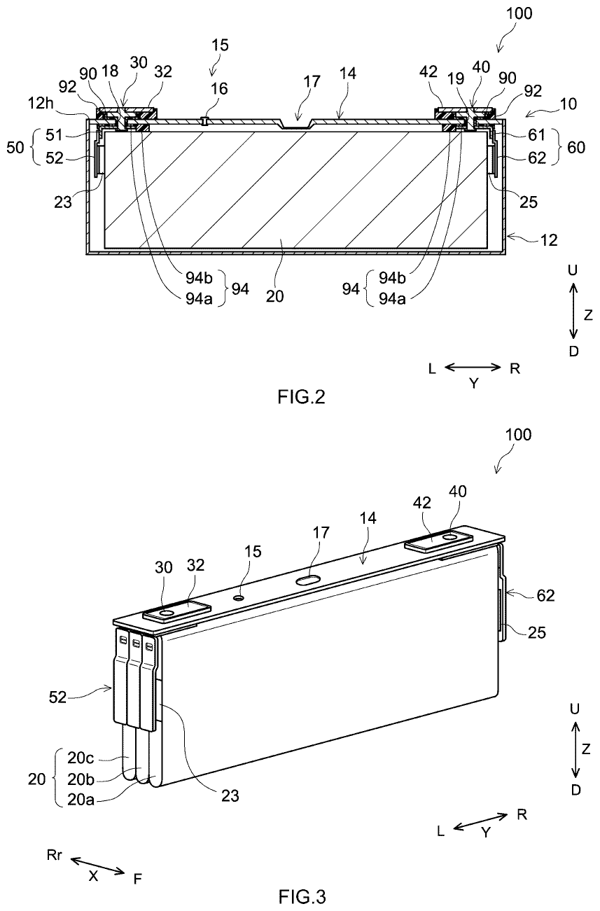

FIG. 1 is a perspective view of a non-aqueous electrolyte secondary battery 100. FIG. 2 is a schematic longitudinal section taken along the line II-II in FIG. 1. It should be noted that in the following description, the sings L, R, F, Rr, U and D in the drawings represent left, right, front, rear, up and down respectively and the signs X, Y and Z in the drawings represent the short side direction, the long side direction perpendicular to the short side direction and the vertical direction respectively in the non-aqueous electrolyte secondary battery 100. The long side direction Y is an example of the first direction disclosed herein and the short side direction is an example of the second direction disclosed herein. However, these are merely directions for the convenience of the description and do not limit the installation mode of the lithium ion secondary battery 100 in any way.

As shown in FIG. 2, the non-aqueous electrolyte secondary battery 100 includes a battery case 10, an electrode body group 20, a positive terminal 30, a negative terminal 40, a positive electrode current collecting part 50 and a negative electrode current collecting part 60. The non-aqueous electrolyte secondary battery 100 further includes a non-aqueous electrolyte solution, which is not shown. The non-aqueous electrolyte secondary battery 100 is a lithium ion secondary battery herein.

The battery case 10 is a housing to hold the electrode body group 20. The battery case 10 has an external form in a flat and cuboid shape (square shape) with the bottom. The material for the battery case 10 is not particularly restricted and may be the same as those which have been conventionally used. The battery case 10 is preferably made of metal and more preferably includes, for example, aluminum, an aluminum alloy, iron or an iron alloy. As shown in FIG. 2, the battery case 10 includes an outer casing 12 having an opening 12h and a sealing plate (cover body) 14 to close the opening 12h.

As shown in FIG. 1, the outer casing 12 includes a bottom wall 12a, a pair of long side walls 12b facing each other and extending from the bottom wall 12a, and a pair of short side walls 12c facing each other and extending from the bottom wall 12a. The bottom wall 12a is in an almost rectangular shape. The bottom wall 12a faces the opening 12h. The area of the short side wall 12c is smaller than the area of the long side wall 12b. The long side wall 12b and the short side wall 12c are an example of the first side wall and the second side wall disclosed herein. The sealing plate 14 is attached to the outer casing 12 to close the opening 12h of the outer casing 12. The sealing plate 14 faces the bottom wall 12a of the outer casing 12. The sealing plate 14 is in an almost rectangular shape in a planar view. The battery case 10 is integrated by joining (e.g. welding junction) the sealing plate 14 to the circumference of the opening 12h of the outer casing 12. The battery case 10 is airtightly sealed (covered tightly).

As shown in FIG. 2, an injection hole 15, a gas release valve 17 and two terminal outlet holes 18 and 19 are provided in the sealing plate 14. The injection hole 15 is to inject an electrolyte solution after putting the sealing plate 14 to the outer casing 12. The injection hole 15 is sealed by a sealing member 16. The gas release valve 17 is configured to discharge the gas in the battery case 10 to the outside by being broken when the pressure in the battery case 10 is not less than a predetermined value. The terminal outlet holes 18 and 19 are each formed at both the ends of the sealing plate 14 in the long side direction Y. The terminal outlet holes 18 and 19 penetrates the sealing plate 14 in the vertical direction Z. The terminal outlet holes 18 and 19 each have an inner diameter with a size through which the positive terminal 30 and the negative terminal 40, respectively, before being attached to the sealing plate 14 (before caulking) can pass.

The positive terminal 30 and the negative terminal 40 are each fixed to the sealing plate 14. The positive terminal 30 is placed on one side of the sealing plate 14 in the long side direction Y (the left side in FIG. 1 and FIG. 2). The negative terminal 40 is placed on the other side of the sealing plate 14 in the long side direction Y (the right side in FIG. 1 and FIG. 2). As shown in FIG. 1, the positive terminal 30 and the negative terminal 40 are exposed to the outer surface of the sealing plate 14. As shown in FIG. 2, the positive terminal 30 and the negative terminal 40 pass through the terminal outlet holes 18 and 19 and extend from the inside to the outside of the sealing plate 14. The positive terminal 30 and the negative terminal 40 are caulked by the circumference of the terminal outlet holes 18 and 19 in the sealing plate 14 by caulking herein. The caulked parts are formed at the ends of the outer casing 12 side of the positive terminal 30 and the negative terminal 40 (the lower end part in FIG. 2).

As shown in FIG. 2, the positive terminal 30 is electrically connected to the positive electrode 22 in the electrode body group 20 via a positive electrode current collecting part 50 in the inside of the outer casing 12. The negative terminal 40 is electrically connected to the negative electrode 24 in the electrode body group 20 via a negative electrode current collecting part 60 in the inside of the outer casing 12. The positive terminal 30 and the negative terminal 40 are an example of terminals disclosed herein.

The positive terminal 30 is preferably made of metal and more preferably includes, for example, aluminum or an aluminum alloy. The negative terminal 40 is preferably made of metal and more preferably includes, for example, copper or a copper alloy. The negative terminal 40 may be formed by joining and integrating two conductive members. For example, a part connected to the negative electrode current collecting part 60 may include copper or a copper alloy and a part exposed to the outer surface of the sealing plate 14 may include aluminum or an aluminum alloy.

As shown in FIG. 1, a plate-shaped external positive electrode conductive member 32 and a plate-shaped external negative electrode conductive member 42 are attached onto the outer surface of the sealing plate 14. The external positive electrode conductive member 32 is electrically connected to the positive terminal 30. The external negative electrode conductive member 42 is electrically connected to the negative terminal 40. The external positive electrode conductive member 32 and the external negative electrode conductive member 42 are members to which a bus bar is attached when a plurality of non-aqueous electrolyte secondary batteries 100 are electrically connected to each other. The external positive electrode conductive member 32 and the external negative electrode conductive member 42 are preferably made of metal and more preferably include, for example, aluminum or an aluminum alloy. The external positive electrode conductive member 32 and the external negative electrode conductive member 42 are insulated from the sealing plate 14 by an external insulating member 92. However, the external positive electrode conductive member 32 and the external negative electrode conductive member 42 are not essential and can be omitted in other embodiments.

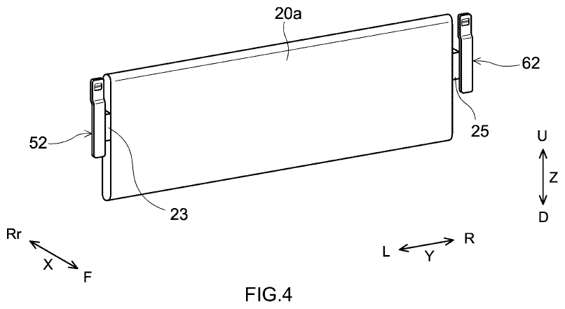

FIG. 3 is a perspective view schematically showing the electrode body group 20 attached to the sealing plate 14. FIG. 4 is a perspective view schematically showing an electrode body 20a. In the non-aqueous electrolyte secondary battery 100 according to the present embodiment, the electrode body group 20 having a plurality of electrode bodies 20a, 20b and 20c is put in the inside of the battery case 10. However, the number of electrode bodies placed in the inside of one outer casing 12 is not particularly limited and may be two or more (plural) or one. The detailed structure thereof will be described below and the electrode bodies 20a, 20b and 20c each have a positive electrode tab group 23 formed from a plurality of positive electrode tabs 22t and a negative electrode tab group 25 formed from a plurality of negative electrode tabs 24t. The positive electrode current collecting part 50 forms a conduction path which electrically connects the positive electrode tab group 23 and the positive terminal 30. In addition, the negative electrode current collecting part 60 forms a conduction path which electrically connects the negative electrode tab group 25 and the negative terminal 40. The positive electrode tab group 23 is at one end of the electrode body 20a and the negative electrode tab group 25 is at the other end.

As shown in FIG. 2, the positive electrode current collecting part 50 includes a first positive electrode current collecting part 51 that is a plate-shaped conductive member extending along the internal surface of the sealing plate 14, and a second positive electrode current collecting part 52 that is a plate-shaped conductive member extending along the vertical direction Z. The lower end part of the positive terminal 30 extends towards the inside of the battery case 10 through the terminal outlet hole 18 in the sealing plate 14 and is connected to the first positive electrode current collecting part 51 (see FIG. 2). As shown in FIG. 2, meanwhile, one end of the second positive electrode current collecting part 52 is connected to the first positive electrode current collecting part 51 and the other end is connected to the positive electrode tab group 23 in the electrode body group 20 to form a connected part J. Herein, the positive electrode tab group 23 in the electrode body group 20 is bent so that the second positive electrode current collecting part 52 and the side having the positive electrode tab group 23 of the electrode bodies 20a, 20b and 20c face each other. By doing this, the width of the positive electrode tab group 23 in the long side direction Y can be reduced. As a result, the coated width in the long side direction Y of a positive electrode active material layer 22a and a negative electrode active material layer 24a described below in the electrode body group 20 can be increased and thus the capacity of the non-aqueous electrolyte secondary battery 100 can be increased. It should be noted that the first positive electrode current collecting part 51 and the second positive electrode current collecting part 52 are preferably made of metal and can be formed from, for example, aluminum, an aluminum alloy, nickel or stainless steel.

As shown in FIG. 2, the negative electrode current collecting part 60 includes a first negative electrode current collecting part 61 that is a plate-shaped conductive member extending along the internal surface of the sealing plate 14, and a second negative electrode current collecting part 62 that is a plate-shaped conductive member extending along the vertical direction Z. The lower end part of the negative terminal 40 extends towards the inside of the battery case 10 through the terminal outlet hole 18 in the sealing plate 14 and is connected to the first negative electrode current collecting part 61 (see FIG. 2). As shown in FIG. 2, meanwhile, one end of the second negative electrode current collecting part 62 is connected to the first negative electrode current collecting part 61 and the other end is connected to the negative electrode tab group 25 in the electrode body group 20 to form a connected part J. Herein, the negative electrode tab group 25 in the electrode body group 20 is bent so that the second negative electrode current collecting part 62 and the side having the negative electrode tab group 25 of the electrode bodies 20a, 20b and 20c face each other. By doing this, the capacity of the non-aqueous electrolyte secondary battery 100 can be increased as with the structure described above in which the positive electrode tab group 23 is bent. It should be noted that the first negative electrode current collecting part 61 and the second negative electrode current collecting part 62 are preferably made of metal and can be formed from, for example, copper, a copper alloy, nickel or stainless steel.

In the non-aqueous electrolyte secondary battery 100 according to the present embodiment, in order to prevent conduction between optional members, various insulating members are attached between the members.

An insulating member to prevent conduction is attached between the battery case 10 and the electrode body group 20. Specifically, an external insulating member 92 exists between the external positive electrode conductive member 32 (or external negative electrode conductive member 42) and the outer surface of the sealing plate 14 (see FIG. 2). This can prevent the external positive electrode conductive member 32 and the external negative electrode conductive member 42 from conducting the sealing plate 14.

A gasket 90 is put on each of the terminal outlet holes 18 and 19 in the sealing plate 14. This can prevent the positive terminal 30 (or negative terminal 40) passing through the terminal outlet hole 18 or 19 from conducting the sealing plate 14.

An internal insulating member 94 is placed between the first positive electrode current collecting part 51 (or first negative electrode current collecting part 61) and the internal surface of the sealing plate 14. This internal insulating member 94 includes a plate-shaped base part 94a existing between the first positive electrode current collecting part 51 (or first negative electrode current collecting part 61) and the internal surface of the sealing plate 14. This can prevent the first positive electrode current collecting part 51 and the first negative electrode current collecting part 61 from conducting the sealing plate 14. The internal insulating member 94 further includes a protruding part 94b protruding from the internal surface of the sealing plate 14 towards the electrode body group 20. This controls the movement of the electrode body group 20 in the vertical direction Z and can prevent direct contacts between the electrode body group 20 and the sealing plate 14.

The material of each insulating member described above is not particularly limited as long as it has a predetermined insulation property. As an example, a synthetic resin material such as a polyolefin-based resin (e.g. polypropylene (PP), polyethylene (PE)) or a fluorine-based resin (e.g. perfluoroalkoxy alkane (PFA), polytetrafluoroethylene (PTFE)) can be used.

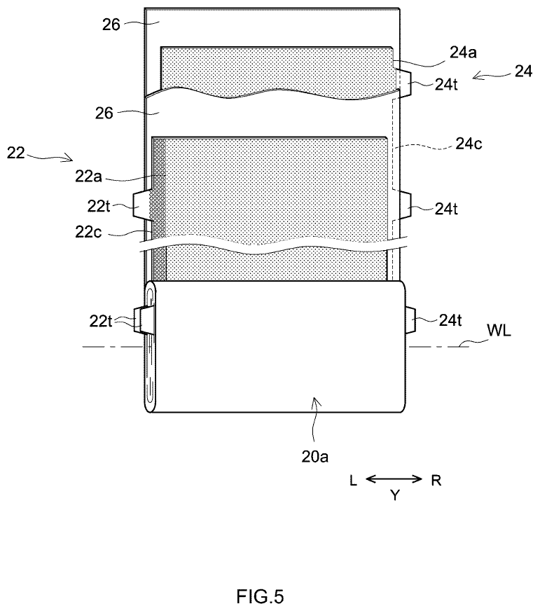

FIG. 5 is a schematic diagram showing the structure of the electrode body 20a. The electrode body 20a will now be described in detail as an example and it should be noted, however, that electrode bodies 20b and 20c may have the same structure. As shown in FIG. 5, the electrode body 20a has the positive electrode 22 and the negative electrode 24. The electrode body 20a herein is a flat-shaped wound electrode body obtained by laminating a strip-shaped positive electrode 22 and a strip-shaped negative electrode 24 with a strip-shaped separator 26 therebetween and winding the obtained laminated body around the winding axis WL as the center. The positive electrode 22 and the negative electrode 24 are an example of the first electrode and the second electrode disclosed herein.

The electrode body 20a is placed in the inside of the outer casing 12 in a direction in which the winding axis WL is parallel to the long side direction Y. In other words, the electrode body 20a is placed in the inside of the outer casing 12 in a direction in which the winding axis WL is parallel to the bottom wall 12a and perpendicular to the short side wall 12c. The end face of the electrode body 20a (in other words, the laminated surface by laminating the positive electrode 22, the negative electrode 24 and the separator 26, the end face in the long side direction Y in FIG. 5) faces the short side wall 12c. However, the electrode body 20a may be also a laminated electrode body obtained by laminating a plurality of square-shaped (typically rectangular-shaped) positive electrodes 22 and a plurality of square-shaped (typically rectangular-shaped) negative electrodes with these electrodes insulated.

As shown in FIG. 5, the positive electrode 22 has a positive electrode substrate 22c and a positive electrode active material layer 22a formed on at least one surface (both surfaces herein) of the positive electrode substrate 22c.

The positive electrode substrate 22c is in a strip shape and includes a conductive metal such as aluminum, an aluminum alloy, nickel or stainless steel. The positive electrode substrate 22c is metal foil herein, specifically aluminum foil.

As shown in FIG. 5, the positive electrode active material layer 22a is provided in a strip shape along the longitudinal direction of the strip-shaped positive electrode substrate 22c and includes a positive electrode active material which can reversibly absorb and release at least a charge carrier. From the viewpoint of reducing the temperature dependence of battery voltage described below, the density of the positive electrode active material layer is preferably 3.0 g/ml or more and more preferably about 3.5 g/ml or 3.5 g/ml or more. From the same viewpoint, the amount of the positive electrode active material layer 24a coated is preferably 380 g/m² or more, more preferably 410 g/m² or more and particularly preferably about 440 g/m² or 440 g/m² or more.

The positive electrode active material preferably includes at least one of at least Ni, Co and Mn and, for example, a lithium transition metal composite oxide such as lithium nickel cobalt manganese composite oxide can be used. When the overall solid content of the positive electrode active material layer 22a is 100 mass %, the positive electrode active material may account for approximately 80 mass % or more, typically 90 mass % or more, for example 95 mass % or more.

The positive electrode active material layer 22a may include optional components other than the positive electrode active material, for example, a conductive material, a binder and various additive components. As the conductive material, a carbon material such as carbon black (e.g. acetylene black (AB)) or carbon nanotube, for example, can be used. As the binder, PVdF, for example, can be used.

As shown in FIG. 5, the negative electrode 24 has a negative electrode substrate 24c and a negative electrode active material layer 24a formed on at least one surface (both surfaces herein) of the negative electrode substrate 24c.

The negative electrode substrate 24c is in a strip shape and includes, for example, a conductive metal such as copper, a copper alloy, nickel or stainless steel. The negative electrode substrate 24c is metal foil herein, specifically copper foil.

As shown in FIG. 5, the negative electrode active material layer 24a is provided in a strip shape along the longitudinal direction of the strip-shaped negative electrode substrate 24c and includes a negative electrode active material which can reversibly absorb and release at least a charge carrier. From the viewpoint of reducing the temperature dependence of battery voltage described below, the density of the negative electrode active material layer is preferably 1.4 g/ml or more and more preferably about 1.5 g/ml or 1.5 g/ml or more. From the same viewpoint, the amount of the negative electrode active material layer 24a coated is preferably 185 g/m² or more, more preferably 220 g/m² or more and particularly preferably about 250 g/m² or 250 g/m² or more.

The negative electrode active material is a negative electrode active material which can reversibly absorb and release a charge carrier (e.g. a carbon material such as graphite, Si, a silicon oxide represented by SiOₓ (0.05<x1.95), a lithium silicon oxide represented by LiₓSi_{y}O_{z} (x, y and z independently meet 0<x, y, z<1) or a lithium-containing lithium-silicon alloy represented by Li₂₁Si₅), and when the overall solid content of the negative electrode active material layer 24a is 100 mass %, the negative electrode active material may account for approximately 80 mass % or more, typically 90 mass % or more, for example 95 mass % or more.

The negative electrode active material layer 24a may include optional components other than the negative electrode active material, for example, a binder, a dispersant and various additive components. As the binder, a rubber such as styrene-butadiene rubber (SBR), for example, can be used. As the dispersant, a cellulose such as carboxymethyl cellulose (CMC), for example, can be used.

The separator 26 is a member to insulate the positive electrode active material layer 22a of the positive electrode 22 and the negative electrode active material layer 24a of the negative electrode 24. As the separator 26, for example, a porous resin sheet including a polyolefin-based resin such as polyethylene (PE) or polypropylene (PP) is suitable. In the separator 26, a heat resistance layer (HRL) including an inorganic filler may be provided on the surface of the above resin sheet. As the inorganic filler, alumina, boehmite, aluminum hydroxide or titania, for example, can be used. It is also preferred that an adhesive layer be provided on one surface or both surfaces of the separator 26. The adhesive layer can improve the adhesive properties to the positive electrode active material layer 22a or the negative electrode active material layer 24a coming into contact therewith. The adhesive layer contains, for example, polyvinylidene difluoride (PVdF) as an adhesive component. The adhesive layer can also include inorganic particles such as alumina or boehmite. The adhesive layer may be provided on the surface of the above resin sheet or the surface of HRL.

The non-aqueous electrolyte solution may be the same as those in the past and is not particularly restricted. The non-aqueous electrolyte solution contains, for example, a non-aqueous solvent and a supporting salt. The non-aqueous solvent includes, for example, a carbonate such as ethylene carbonate, dimethyl carbonate or ethyl methyl carbonate. The supporting salt is, for example, a fluorine-containing lithium salt such as LiPF₆. However, the non-aqueous electrolyte solution may be in a solid form (solid electrolyte) and integrated with the electrode body group 20.

### 2. Method for Manufacturing Non-Aqueous Electrolyte Secondary Battery

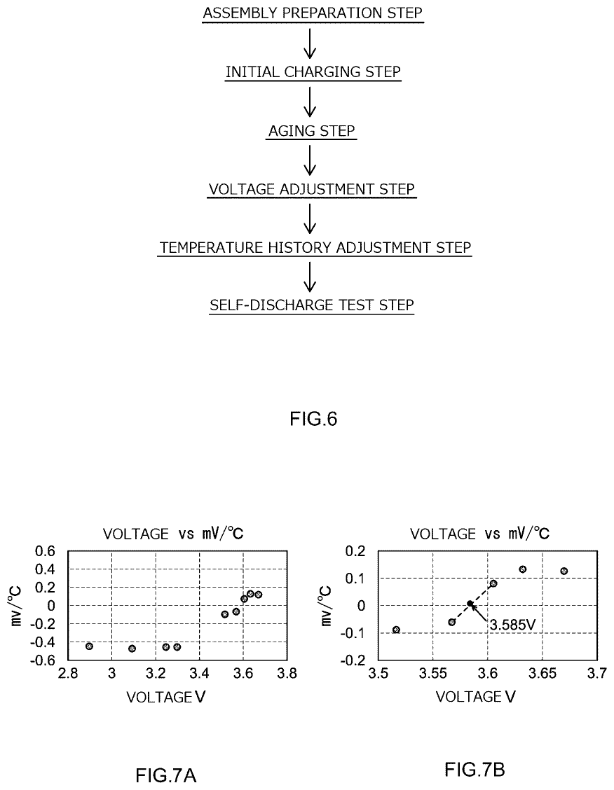

FIG. 6 is a flow chart showing part of the method for manufacturing a non-aqueous electrolyte secondary battery. Each step will now be described.

### <Assembly Preparation Step>

In an assembly preparation step, the above electrode body and the above non-aqueous electrolyte are put in the above battery case to prepare an assembly. In this specification, the “assembly” refers to a non-aqueous electrolyte secondary battery before performing an initial charging step described below.

### <Initial Charging Step>

In the initial charging step, the above assembly is charged to a predetermined voltage V0. Specifically, electrodes in an external battery charger are connected to electrode terminals in the above assembly, which is charged to a predetermined voltage V0 at normal temperature (e.g. about 20° C. to 30° C.).

Examples of the charging treatment at this time include constant current constant voltage charging (CC-CV charging) including constant current charging at about 0.1 C to 10 C until the voltage between the terminals (the voltage between the positive electrode and the negative electrode) reaches a predetermined value and then constant voltage charging until the battery voltage reaches about 3.4 V to 3.6 V. However, the conditions of the charging treatment in this step are not particularly limited and can be appropriately changed depending on the standards of the non-aqueous electrolyte secondary battery, a manufacturing target.

It should be noted that the number of the charging treatments in this step is not particularly limited. In this step, for example, a charging and discharging cycle having combination of a charging treatment and a discharging treatment may be repeated several times.

In the initial charging of the non-aqueous electrolyte secondary battery, the electrode active material can decompose organic matter such as electrolyte solution components and additives which come into contact therewith at not less than a predetermined potential. The decomposed products are deposited on the surface of the electrode active material as an SEI membrane. That is, the SEI membrane is formed by mixing of the decomposed products of e.g. the electrolyte solution components and additives. The SEI membrane does not have electron conductivity but is not a complete continuous membrane and thus allows ions to pass through. Therefore, the SEI membrane stabilizes and deactivates the surface of the electrode active material and can inhibit excessive decomposition of e.g. the electrolyte solution components.

From the viewpoint of forming a good SEI membrane in the initial charging step, the above predetermined voltage V0 is preferably 3.48 V or more and may be 3.54 V or more or 3.58 V or more.

### <Aging Step>

In an aging step, the assembly after the above initial charging step is retained under a high temperature environment. Excess components of the SEI membrane formed on the surface of the negative electrode in the initial charging step described above are decomposed by performing the aging step to modify the SEI membrane.

It should be noted that the conditions of the aging step can be appropriately adjusted depending on aspects for SEI membrane modification required and are not particularly limited. The aging temperature in the aging step, for example, can be 30° C. or higher, preferably 40° C. or higher, for example 50° C. or higher and moreover 60° C. or higher. The upper limit of the aging temperature is not particularly restricted and about 80° C. or lower, for example, can be used as a standard. The temperature in the aging step can be managed using, for example, a thermostatic bath. The time for the aging step (aging time) can be appropriately changed depending on, for example, the aging temperature and is not particularly limited. When the aging temperature is about 45 to 70° C., for example, the aging time is preferably about 3 to 20 hours. When the aging temperature is about 70 to 75° C., the aging time is preferably about one to 15 hours.

In the aging step, aging is preferably performed while applying load to the assembly in the short side direction X. The amount of load applied to the assembly in the aging step is not particularly limited and is preferably 0.5 to 0.7 MPa.

### <Voltage Adjustment Step>

In a voltage adjustment step, the above assembly after the above aging step is adjusted to a predetermined voltage V1. The temperature of the non-aqueous electrolyte secondary battery when performing the voltage adjustment step is only needed to be lower than the temperature when performing the aging step and may be, for example, normal temperature (about 20 to 30° C.). It should be noted that the non-aqueous electrolyte secondary battery may be intentionally cooled to normal temperature or allowed to cool naturally between after the aging step and the start of the voltage adjustment step. The predetermined voltage V1 is decided by the temperature dependence of battery voltage. In the manufacture of the non-aqueous electrolyte secondary battery according to the present disclosure, therefore, it is needed to measure the temperature dependence of battery voltage at any charging voltage as advance preparations in a secondary battery which is supposed to be actually used. In this specification, the temperature dependence of battery voltage refers to the amount of change in the battery voltage with temperature change per unit amount of the battery.

As a method for deriving the above temperature dependence of battery voltage, the charging voltage of the non-aqueous electrolyte secondary battery is adjusted to any value (e.g. 3.5 V) and then battery voltages (v1, v2) at any two temperatures (e.g. t1=25° C., t2=30° C.) are measured. After that, it is derived by the following formula (1):

Temperature dependence of battery voltage=(v2−v1)/(t2−t1) Formula (1).

Then, when the temperature dependence of battery voltage is >0, the temperature dependence of battery voltage in the non-aqueous electrolyte secondary battery is considered positive.

FIG. 7(A) is a graph showing the temperature dependence of battery voltage at any charging voltages measured under a 25° C. environment. FIG. 7(B) is an enlarged graph of part of FIG. 7(A). It should be noted that it is not needed to perform a self-discharge test at 25° C. and the temperature is not limited. As shown in FIG. 7, in the non-aqueous electrolyte secondary battery according to the present disclosure, when the charging voltage is lower than 3.585 V, the temperature dependence of battery voltage is a negative value. On the other hand, when the charging voltage is 3.585 V or higher, the temperature dependence of battery voltage is a positive value.

When the temperature dependence of battery voltage is a positive value, the battery voltage increases with increases in the battery temperature. However the negative electrode potential increases with increases in the battery temperature at this time, a charge carrier (lithium ion herein) forming the electric double layer on the interface of the negative electrode is released from the vicinity of the interface of the negative electrode into the electrolyte and depending on changes in the concentration thereof along with that, the negative electrode potential is reduced. After that, when the battery is cooled and returned to the original temperature, in a case where the above charge carrier is not completely returned into the electric double layer on the interface of the negative electrode, a reduction in the negative electrode potential is maintained in just that amount and an increase in the battery voltage occurs in the whole battery. Furthermore, in the non-aqueous electrolyte secondary battery after the above temperature change process, the concentration of the charge carrier in the electric double layer on the interface of the negative electrode is relatively smaller (the released charge carrier is not completely returned), and thus changes in the concentration of the charge carrier in the electric double layer are smaller even when the temperature is changed thereafter and the battery voltage does not easily vary. It should be noted that the description of the action mechanism of the technique described above is a presumption and does not limit this technique.

The predetermined voltage V1 is preferably 3.585 V or more, more preferably 3.600 V or more and particularly preferably 3.800 V or more from the viewpoint that the temperature dependence of battery voltage in the non-aqueous electrolyte secondary battery according to the present disclosure is obtained as a positive value and the viewpoint of suitably achieving the effect of reducing the absolute value thereof.

### <Temperature History Adjustment Step>

In a temperature history adjustment step, the temperature at the start of a temperature raise of the above assembly after the above voltage adjustment step is considered T1, the above assembly is subjected to a temperature raise to a temperature T2 higher than the above T1 and the above assembly is then subjected to a temperature reduction to a temperature T3 lower than the above T2.

The above T1 is a temperature of the non-aqueous electrolyte secondary battery when starting the temperature history adjustment step, and is not particularly limited and may be, for example, normal temperature (e.g. about 20 to 30° C.). A temperature difference between the above T1 and the above T2 is preferably 3° C. or higher, more preferably 5° C. or higher and particularly preferably 7° C. or higher from the viewpoint of suitably achieving a reduction in the temperature dependence of battery voltage in the non-aqueous electrolyte secondary battery according to the present disclosure. It should be noted that the upper limit of the above temperature difference is not particularly limited and may be, for example, 20° C. or lower or 15° C. or lower. The method for a temperature raise of the assembly from the above T1 to the above T2 is not particularly limited and a thermostat bath, for example, may be used.

The above T3 is a temperature when finishing the temperature history adjustment step, and is only needed to meet the above standard and may be the same as the above T1 or have a different value. It should be noted that the method for a temperature reduction of the assembly from the above T2 to the above T3 is not particularly limited and a thermostat bath, for example, may be used. It should be noted that the retention time after reaching the above T2 or T3 is preferably 24 hours or longer, more preferably 36 hours or longer and particularly preferably 48 hours or longer from the viewpoint of reducing the temperature dependence of battery voltage in the non-aqueous electrolyte secondary battery according to the present disclosure.

In one suitable aspect of the method for manufacturing a non-aqueous electrolyte secondary battery disclosed herein, the above temperature history adjustment step is performed once or twice or more repeatedly. When the step is repeated twice or more, temperature differences δT between the above T2 and the above T1 in the respective temperature history adjustment steps may be the same as or different from each other. It should be noted that the temperature reduction is not necessarily required after the temperature raise and the above temperature history adjustment step may be finished after the temperature raise of the non-aqueous electrolyte secondary battery.

### <Self-Discharge Test Step>

The self-discharge test is performed at a temperature T4 lower than the above T2 after the above temperature history adjustment step. The above T4 is a temperature when starting the self-discharge test step, and is only needed to meet the above standard and may be the same as T3 or have a different value. The temperature difference between the above T2 and the above T4 is preferably 3° C. or higher, more preferably 5° C. or higher and particularly preferably 7° C. or more from the viewpoint of suitably achieving a reduction in the temperature dependence of battery voltage in the non-aqueous electrolyte secondary battery according to the present disclosure.

In the self-discharge test, the assembly after the temperature history adjustment step is retained at normal temperature (e.g. about 20 to 30° C.) and the amount of battery voltage reduced by self-discharge is measured. Then, the assembly is tested about whether or not an internal short circuit occurs (whether or not the assembly is a good product) based on the amount of reduced battery voltage. In batteries having an internal short circuit, the amount of discharge by self-discharge is greater and a difference in battery voltage before and after self-discharge tends to be greater than those of batteries without an internal short circuit. It should be noted that the method for adjusting a temperature when performing the self-discharge test is not particularly limited and a thermostat bath, for example, may be used.

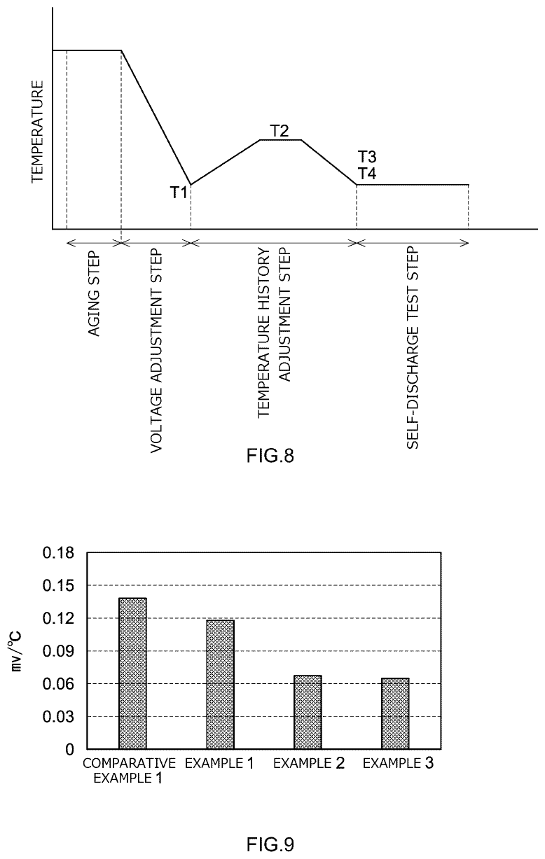

FIG. 8 is a graph schematically showing the temperature change process of the assembly in the manufacturing process. Then, the method for manufacturing a non-aqueous electrolyte secondary battery according to the present disclosure includes the steps described above. It should be noted that as the subsequent manufacturing steps, it can be manufactured in accordance with conventionally known manufacturing methods.

### 1. TEST EXAMPLES

Test Examples related to the technique disclosed herein will now be described. It should be noted, however, that the technique disclosed herein is not limited to such Test Examples.

### (1) Assembly Preparation Step

### Examples 1 to 3

A lithium nickel cobalt manganese composite oxide (NCM) as a positive electrode active material, polyvinylidene difluoride (PVdF) as a binder and carbon nanotube (CNT) as a conductive material were weighed so that the mass ratio was NCM:PVdF:CNT=97.5:1.5:1 and mixed in N-methyl-2-pyrrolidone (NMP) to prepare positive electrode slurry with a density of 3.55 g/mL. Both surfaces of a long and strip-shaped positive electrode substrate (aluminum foil, thickness 12 μm) were coated with this positive electrode slurry, which was dried. This was cut out into a predetermined size and rolled by a roll press to obtain a positive electrode sheet having a positive electrode active material layer on both surfaces of the positive electrode substrate in a coated amount of 450 g/m².

Next, natural graphite (C) as a negative electrode active material, styrene butadiene rubber (SBR) as a binder and carboxymethyl cellulose (CMC) as a thickener were weighed so that the mass ratio was C:SBR:CMC=98.5:1:0.5 and mixed in water to prepare negative electrode slurry with a density of 1.50 g/mL. Both surfaces of a long and strip-shaped negative electrode substrate (copper foil, 9 μm) were coated with this negative electrode slurry, which was dried. This was cut out into a predetermined size and rolled by a roll press to obtain a negative electrode sheet having a negative electrode active material layer on both surfaces of the negative electrode substrate in a coated amount of 250 g/m².

Then, a separator having a three layer structure of PE/PP/PE and a thickness of 14 μm was prepared and the positive electrode sheet, the separator and the negative electrode sheet were laminated in this order. Electrode terminals were attached to the produced electrode body, which was then put with a non-aqueous electrolyte in a battery case.

As the non-aqueous electrolyte, an electrolyte obtained by dissolving LiPF₆ as a supporting salt at a concentration of 1.15 mol/L in a mixed solvent including ethylene carbonate (EC), dimethyl carbonate (DMC) and ethyl methyl carbonate (EMC) in a volume ratio of EC:DMC:EMC=3:3:4, was used.

### Comparative Example 1

An assembly was produced in the same manner as in Examples 1 to 3.

### (2) Preparation for Evaluation Test

### Example 1

### Initial Charging Step

The assembly prepared in the assembly preparation step was subjected to initial charging by constant current charging at a current value of 0.1 C to a predetermined upper limit voltage and then constant current discharging to 3.58 V under a 25° C. environment.

### Aging Step

The assembly after the initial charging was retained under a 57° C. environment for 6 hours.

### Voltage Adjustment Step

The assembly after the aging step was allowed to cool to 25° C. and then charged and discharged, and the charging voltage was set to 3.603 V.

### Temperature History Adjustment Step

The assembly at 25° C. (T1) was retained under a 30° C. environment for 24 hours and subjected to a temperature raise to 30° C. (T2) after the voltage adjustment step. After that, the assembly was cooled to 25° C. (T3 and T4).

### Example 2

The preparation for the evaluation test was performed in the same manner as in Example 1 except that the above temperature raise was performed twice after the voltage adjustment step. It should be noted that the non-aqueous electrolyte secondary battery was intentionally cooled using a 25° C. thermostat bath between the first and the second temperature raises.

### Example 3

The preparation for the evaluation test was performed in the same manner as in Example 1 except that the above temperature raise was performed three times after the voltage adjustment step. It should be noted that the non-aqueous electrolyte secondary battery was intentionally cooled using a 25° C. thermostat bath between the first and the second temperature raises and between the second and third temperature raises.

### Comparative Example 1

The preparation for the evaluation test was performed in the same manner as in Examples 1 to 3 except that the temperature history adjustment step was not performed.

### 2. EVALUATION TEST

### Examples 1 to 3

The voltage E1 was measured in the above assembly at 30° C. (T2) at the final temperature raise in the temperature history adjustment step and the voltage E2 was then measured after retaining under a 25° C. environment for 24 hours (at T4) in each Example. The temperature dependence of battery voltage was measured by dividing a difference between E2 and E1 by the amount of temperature change.

### Comparative Example 1

The voltage E1 was measured in the assembly at 25° C. (corresponding to T4) after the voltage adjustment step (without performing the temperature history adjustment step) and the voltage E2 was then measured after retaining under a 30° C. environment for 24 hours. The temperature dependence of battery voltage was measured by dividing a difference between E2 and E1 by the amount of temperature change. That is, temperatures when measuring E1 and E2 are opposite to each other between Examples 1 to 3 and Comparative Example 1.

The test results are summarized in Table 1-1, 1-2 and FIG. 9.

TABLE 1-1

| | Number of | | |
|---|---|---|---|
| | temperature history | | Comparative |
| | adjustment steps | | Example 1 |
| Temperature | T1_1st time [° C.] | 1st | 25 |
| history | T2_1st time [° C.] | time | — |
| | T3_1st time [° C.] | | — |
| | T1_2nd time [° C.] | 2nd | — |
| | T2_2nd time [° C.] | time | — |
| | T3_2nd time [° C.] | | — |
| | T1_3rd time [° C.] | 3rd | — |
| | T2_3rd time [° C.] | time | — |
| | T3_3rd time [° C.] | | — |
| | T4 [° C.] | | 25 |
| Negative electrode | Density [g/mL] | | 1.50 |
| active material | Coated amount [g/m³] | | 250 |
| Data used | E1 [mV] | | 3603.097 (Voltage |
| to calculate | | | at T4) |
| temperature | E2 [mV] | | 3603.776 (Voltage |
| dependence of | | | after retaining |
| battery voltage | | | at 30° C. after T4) |

| | |
|---|---|
| E2 − E1 [mV] | 0.679 |
| Amount of | 4.9 |
| temperature change [° C.] | |
| Temperature dependence | 0.139 |
| of battery voltage [mV/° C.] | |

Voltage at 25° C. is E1 and voltage at 30° C. is E2 in Comparative Example 1.

TABLE 1-2

| | Number of | | | | |
|---|---|---|---|---|---|
| | temperature history | | | | |
| | adjustment steps | | Example 1 | Example 2 | Example 3 |
| Temperature | T1_1st time [° C.] | 1st time | 25 | 25 | 25 |
| history | T2_1st time [° C.] | | 30 | 30 | 30 |
| | T3_1st time [° C.] | | 25 | 25 | 25 |
| | T1_2nd time [° C.] | 2nd time | — | 25 | 25 |
| | T2_2nd time [° C.] | | — | 30 | 30 |
| | T3_2nd time [° C.] | | — | 25 | 25 |
| | T1_3rd time [° C.] | 3rd time | — | — | 25 |
| | T2_3rd time [° C.] | | — | — | 30 |
| | T3_3rd time [° C.] | | — | — | 25 |
| | T4 [° C.] | | 25 | 25 | 25 |
| Negative electrode | Density [g/mL] | | 1.50 | 1.50 | 1.50 |
| active material | Coated amount [g/m²] | | 250 | 250 | 250 |
| Data used | E1 [mV] | | 3603.776 (Voltage | 3603.860 (voltage | 3603.860 (Voltage |
| to calculate | | | at T2_1st time) | at T2_2nd time) | at T2_3rd time) |
| temperature | E2 [mV] | | 3603.219 (Voltage | 3603.520 (Voltage | 3603.530 (Voltage |
| dependence of | | | at T4) | at T4) | at T4) |

| | | | | |
|---|---|---|---|---|
| battery voltage | E2 − E1 [mV] | −0.557 | −0.340 | −0.330 |
| | Amount of | −4.7 | −4.9 | −5.0 |
| | temperature change [° C.] | | | |
| | Temperature dependence | 0.119 | 0.069 | 0.066 |
| | of battery voltage [mV/° C.] | | | |

Voltage at 30° C. is E1 and voltage at 25° C. is E2 in Examples 1 to 3.

In Examples 1 to 3, the temperature dependence of battery voltage showed a positive value and the absolute value thereof was relatively smaller. In addition, as the number of temperature raises increases, the effect of reducing temperature dependence was more remarkably observed. In Comparative Example 1, meanwhile, the charging voltage was adjusted to 3.585 V or more in the voltage adjustment step so that the temperature dependence of battery voltage was a positive value; however, the temperature history was not adjusted and thus the absolute value thereof was relatively greater.

The detailed description has been described above by way of specific embodiments. It should be noted, however, that these are merely examples and do not limit the claims. Various variants and modifications of the embodiments described above are encompassed in the technique described in the claims.

### REFERENCE SIGN LIST

10 Battery case
12 Outer casing
14 Sealing plate
20 Electrode body group
20a, 20b, 20c Electrode body
22 Positive electrode
22a Positive electrode active material layer
22c Positive electrode substrate
22t Positive electrode tab
24 Negative electrode
24a Negative electrode active material layer
24c Negative electrode substrate
24t Negative electrode tab
26 Separator
30 Positive terminal
40 Negative terminal
50 Positive electrode current collecting part
60 Negative electrode current collecting part
100 Non-aqueous electrolyte secondary battery

What is claimed is:

1. A method for manufacturing a non-aqueous electrolyte secondary battery comprising
an electrode body comprising a positive electrode and a negative electrode, and
a non-aqueous electrolyte,
the method comprising steps:
an assembly preparation step of preparing an assembly having the electrode body and the non-aqueous electrolyte put in a battery case;
an initial charging step of charging the assembly to a predetermined voltage V0;
an aging step of storing the assembly at 45° C. or higher for 3 hours or longer after the initial charging step;
a voltage adjustment step of adjusting the assembly to a voltage V1 of 3.585 V or higher after the aging step;
a temperature history adjustment step of, when a temperature at start of a temperature raise of the assembly is considered T1, comprising a temperature raise of the assembly to a temperature T2 higher than the T1 and then a temperature reduction of the assembly to a temperature T3 lower than the T2 after the voltage adjustment step; and
a self-discharge test step of performing a self-discharge test at a temperature T4 lower than the T2 after the temperature history adjustment step.

2. The method for manufacturing a non-aqueous electrolyte secondary battery according to claim 1,
wherein the negative electrode comprises a negative electrode substrate and a negative electrode active material layer formed on at least one surface of the negative electrode substrate, and
a density of the negative electrode active material layer is 1.4 g/mL or more and a coated amount is 185 g/m² or more.

3. The method for manufacturing a non-aqueous electrolyte secondary battery according to claim 1, wherein the temperature history adjustment step is performed once or twice or more repeatedly and, when the step is repeated twice or more, temperature differences δT between the T2 and the T1 in the respective temperature history adjustment steps are same as or different from each other.

4. The method for manufacturing a non-aqueous electrolyte secondary battery according to claim 2, wherein the temperature history adjustment step is performed once or twice or more repeatedly and, when the step is repeated twice or more, temperature differences δT between the T2 and the T1 in the respective temperature history adjustment steps are same as or different from each other.

5. The method for a manufacturing a non-aqueous electrolyte secondary battery according to claim 3, wherein a temperature difference between the T2 and the T4 is 3° C. or higher.

6. The method for a manufacturing a non-aqueous electrolyte secondary battery according to claim 4, wherein a temperature difference between the T2 and the T4 is 3° C. or higher.
